(19) United States
(12) Patent Application Publication
(10) Pub. No.: US 2026/0040550 A1
(43) Pub. Date: Feb. 5, 2026

(54) MICROELECTRONIC DEVICES INCLUDING STADIUM STRUCTURES, AND RELATED MEMORY DEVICES AND ELECTRONIC SYSTEMS

(71) Applicant: Micron Technology, Inc., Boise, ID (US)

(72) Inventors: Anna Maria Conti, Milano (IT); Lifang Xu, Boise, ID (US)

(21) Appl. No.: 19/255,517

(22) Filed: Jun. 30, 2025

Related U.S. Application Data
(60) Provisional application No. 63/678,001, filed on Jul. 31, 2024.

(51) Int. Cl. H10B 43/27; G11C 5/06; H10B 41/10; H10B 41/27; H10B 41/35; H10B 43/10; H10B 43/35

(52) U.S. Cl. CPC H10B 43/27; G11C 5/063; H10B 41/10; H10B 41/27; H10B 41/35; H10B 43/10; H10B 43/35

(57) ABSTRACT

A microelectronic device includes a stack structure divided into blocks, dielectric-filled slot structures, and further dielectric-filled slot structures. The stack structure includes tiers of conductive and insulative structures. A block includes a stadium structure, a crest region, and bridge regions. A first group of the dielectric-filled slot structures extends in a first direction and terminates within the stadium structure. A second group of the dielectric-filled slot structures extends in the first direction across the stadium structure and terminates within the crest region. The further dielectric-filled slot structures extends in a second direction partially into the crest region. The further dielectric-filled slot structures the second group of the additional dielectric-filled slot structures within the crest region. The dielectric-filled slot structures and the further dielectric-filled slot structures extend vertically through upper tiers of the sack structure. A memory device and an electronic system are also described.

### CROSS-REFERENCE TO RELATED APPLICATIONS

This application claims the benefit under 35 U.S.C. § 119 (e) of U.S. Provisional Patent Application Ser. No. 63/678,001, filed Jul. 31, 2024, the disclosure of which is hereby incorporated herein in its entirety by this reference.

### TECHNICAL FIELD

The disclosure, in various embodiments, relates generally to the field of microelectronic device design and fabrication. More specifically, the disclosure relates to microelectronic devices, memory devices, and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often seek to design architectures that are not only compact, but offer performance advantages, as well as simplified designs.

One example of a microelectronic device is a memory device. Memory devices are generally provided as internal integrated circuits in computers or other electronic devices. There are many types of memory devices including, but not limited to, non-volatile memory devices (e.g., NAND Flash memory devices). One way of increasing memory density in non-volatile memory devices is to utilize vertical memory array (also referred to as a “three-dimensional (3D) memory array”) architectures. A conventional vertical memory array includes strings of memory cells vertically extending through one or more stack structures including tiers of conductive material and insulative material. Each string of memory cells may include at least one select device coupled thereto. Such a configuration permits a greater number of switching devices (e.g., transistors) to be located in a unit of die area (i.e., length and width of active surface consumed) by building the array upwards (e.g., vertically) on a die, as compared to structures with conventional planar (e.g., two-dimensional) arrangements of transistors.

Vertical memory array architectures generally include electrical connections between the conductive material of the tiers of the stack structure(s) of the memory device and control logic devices (e.g., string drivers) so that the memory cells of the vertical memory array can be uniquely selected for writing, reading, or erasing operations. One method of forming such an electrical connection includes forming so-called “staircase” (or “stair step”) structures at edges (e.g., horizontal ends) of the tiers of the stack structure(s) of the memory device. The staircase structure includes individual “steps” defining contact regions for the conductive material of the tiers, upon which conductive contact structures can be positioned to provide electrical access to the conductive material. In turn, conductive routing structures can be employed to couple the contact structures to the control logic devices. Unfortunately, as feature packing densities have increased and margins for formation errors have decreased, conventional fabrication methods and resulting structural configurations have resulted in undesirable defects that can diminish desired memory device performance, reliability, and durability.

### BRIEF DESCRIPTION OF THE DRAWINGS

FIG. 1A is a simplified, partial perspective view of a portion of a microelectronic device structure, in accordance with embodiments of the disclosure. FIG. 1B is a simplified, partial longitudinal cross-sectional view of the microelectronic device structure 100, orthogonal to a dashed box A depicted in FIG. 1A. FIG. 1C is a simplified, partial longitudinal cross-sectional view of the microelectronic device structure 100, along the dashed box A depicted in FIG. 1A. FIG. 1D is a simplified, partial top-down view of the microelectronic device structure 100 depicted in FIG. 1A.

FIG. 2 is a simplified, partial top-down view of the microelectronic device structure of FIGS. 1A through 1D, including signal routing paths facilitated by a structural configuration of the microelectronic device structure, in accordance with embodiments of the disclosure.

FIG. 3 is a simplified, partial cutaway perspective view of a memory device, in accordance with embodiments of the disclosure.

FIG. 4 is a schematic block diagram illustrating an electronic system, in accordance with embodiments of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessarily limited to memory functionality. Stated another way, and by way of non-limiting example only, the term “memory device” includes not only conventional memory (e.g., conventional volatile memory, such as conventional dynamic random access memory (DRAM); conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, the term “configured” refers to a size, shape, material composition, orientation, and arrangement of one or more of at least one structure and at least one apparatus facilitating operation of one or more of the structure and the apparatus in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., regions, structures, devices) described as “neighboring” one another means and includes features of the disclosed identity (or identities) that are located most proximate (e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, spatially relative terms, such as “beneath,” “below,” “lower,” “downward,” “bottom,” “above,” “upper,” “upward,” “top,” “front,” “rear,” “left,” “right,” “side,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, any ordinal terms, such as “first,” “second,” etc., is used for clarity and convenience in understanding the disclosure and accompanying drawings or to distinguish one claimed construct from another, and do not connote or depend on any specific sequence, preference, time, uniqueness, or order, except where the context clearly indicates otherwise.

As used herein, the singular forms “a,” “an,” and “the” are intended to include the plural forms as well, unless the context clearly indicates otherwise.

As used herein, “and/or” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fc), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative material” means and includes electrically insulative material, such as one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). In addition, an “insulative structure” means and includes a structure formed of and including insulative material.

As used herein, the term “semiconductor material” refers to a material having an electrical conductivity between those of insulative materials and conductive materials. For example, a semiconductor material may have an electrical conductivity of between about 10-8 Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., GaxIn_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO)), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn₂O), and other similar materials.

Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative structure may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

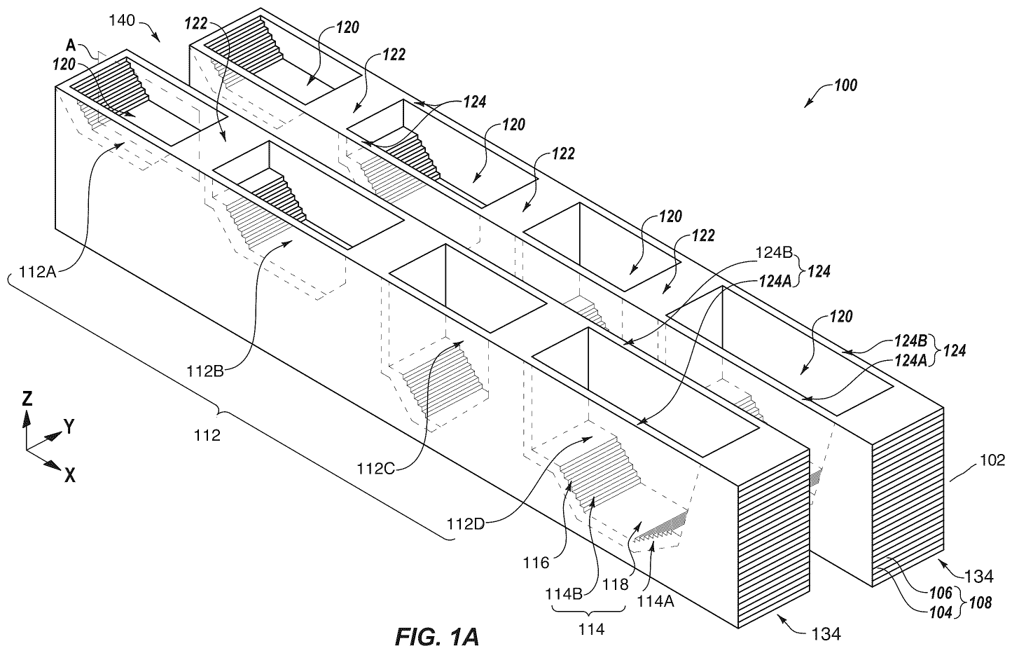

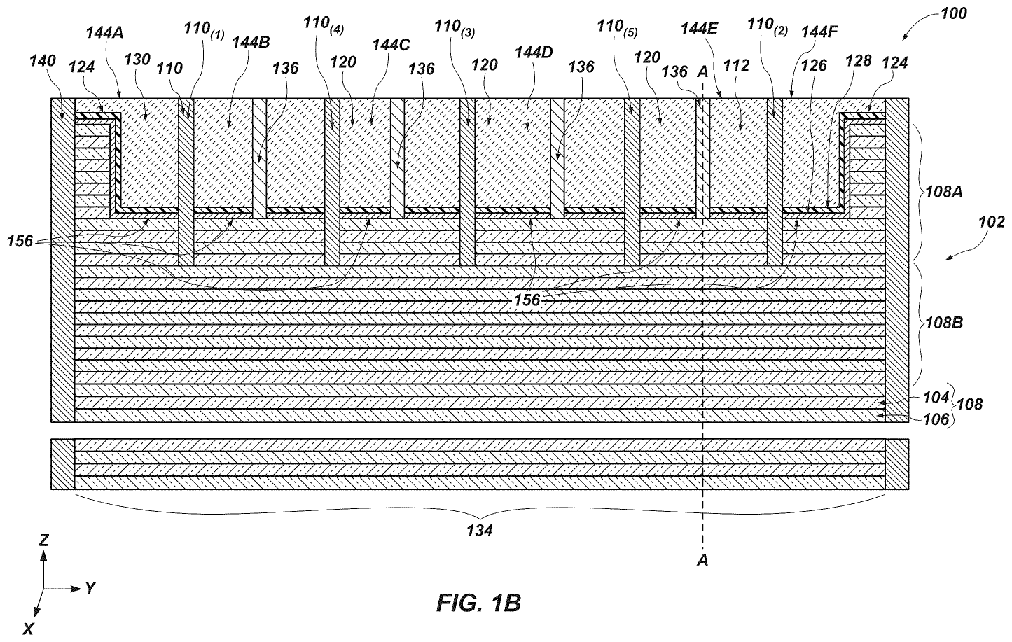

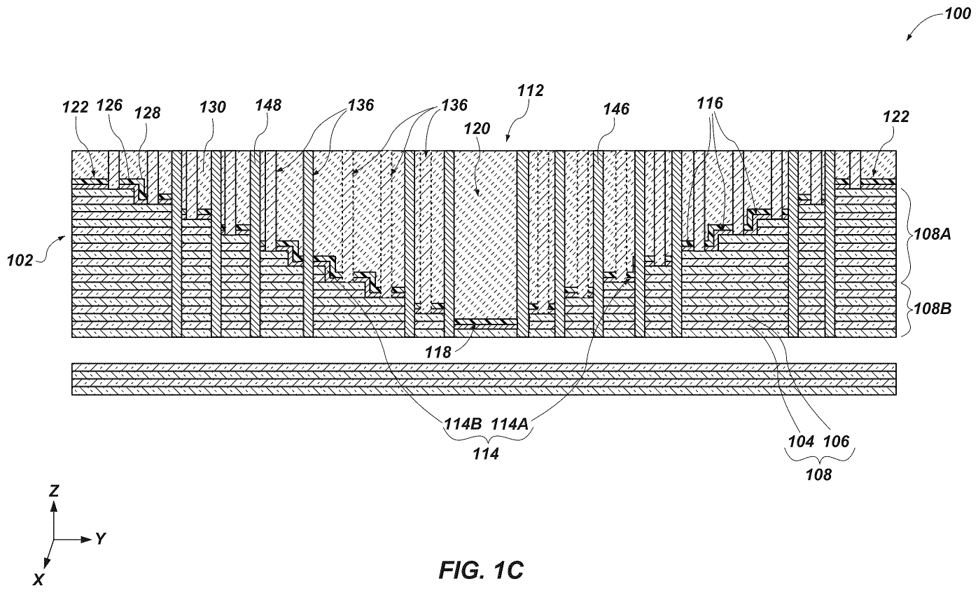

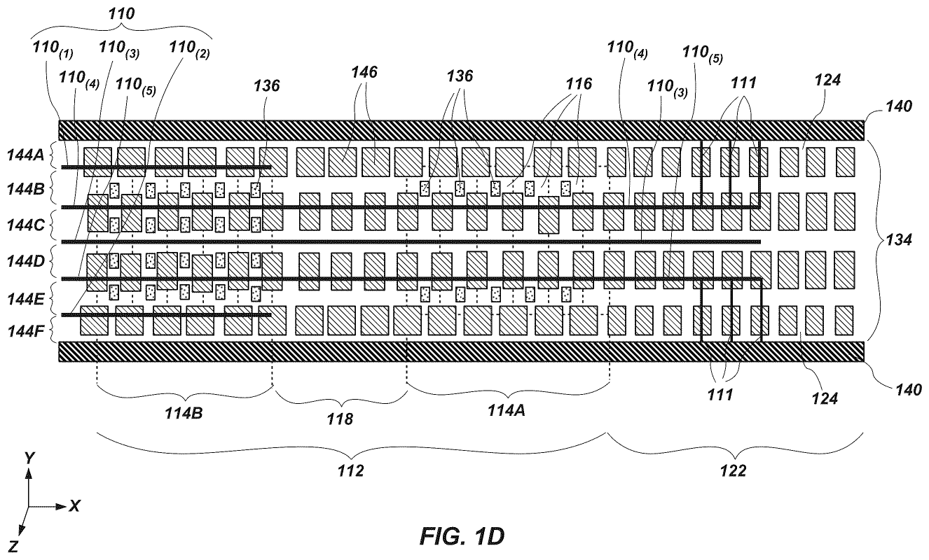

FIGS. 1A through 1D are various views (described in further detail below) illustrating a microelectronic device structure 100 for a microelectronic device (e.g., a memory device, such as a 3D NAND Flash memory device), in accordance with embodiments of the disclosure. With the description provided below, it will be readily apparent to one of ordinary skill in the art that the structures (e.g., the microelectronic device structure 100) and devices (e.g., microelectronic devices) described herein may be employed in various relatively larger devices and/or systems. For clarity and case of understanding the drawings and associated description, not all features (e.g., regions, structures, materials, devices) of the microelectronic device structure 100 shown in one or more of FIGS. 1A through 1D are depicted in one or more other of FIGS. 1A through 1D.

FIG. 1A is a simplified, partial perspective view of a microelectronic device structure 100. FIG. 1B is a simplified, partial longitudinal cross-sectional view of the microelectronic device structure 100, orthogonal to a dashed box A depicted in FIG. 1A. FIG. 1C is a simplified, partial longitudinal cross-sectional view of the microelectronic device structure 100, along the dashed box A depicted in FIG. 1A. FIG. 1D is a simplified, partial top-down view of the microelectronic device structure 100 depicted in FIG. 1A.

For convenience in describing figures herein, a first horizontal direction may be defined as the X-direction; and a second horizontal direction that is orthogonal (e.g., perpendicular) to the first horizontal direction may be defined as the Y-direction. A vertical direction that is perpendicular to each of the first horizontal direction and the second horizontal direction may be defined as the Z-direction.

As shown in FIGS. 1A through IC, the microelectronic device structure 100 may include a stack structure 102 including a vertically alternating (e.g., in a Z-direction) sequence of insulative structures 104 and conductive structures 106 arranged in tiers 108. The insulative structures 104 may be vertically interleaved with the conductive structures 106. Each of the tiers 108 of the stack structure 102 may individually include a conductive structure 106 vertically neighboring (e.g., directly vertically adjacent) an insulative structure 104. The stack structure 102 may be formed to include any desired quantity of the tiers 108. By way of non-limiting example, the stack structure 102 may be formed to include greater than or equal to sixteen (16) of the tiers 108, such as greater than or equal to thirty-two (32) of the tiers 108, greater than or equal to sixty-four (64) of the tiers 108, greater than or equal to one hundred and twenty-eight (128) of the tiers 108, or greater than or equal to two hundred and fifty-six (256) of the tiers 108. The tiers 108 of the stack structure 102 may include a group of relatively vertically higher tiers (upper tiers) 108A, and a group of relatively vertically higher tiers (lower tiers) 108B.

The insulative structures 104 of the tiers 108 of the stack structure 102 may individually be formed of and include insulative material, such as one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and MgOₓ), at least one dielectric nitride material (e.g., SiN_{y}), at least one dielectric oxynitride material (e.g., SiOₓN_{y}), and at least one dielectric carboxynitride material (e.g., SiOₓC_{z}N_{y}). In some embodiments, the insulative structures 104 of the tiers 108 of the stack structure 102 are individually formed of and include a dielectric oxide material, such as SiOₓ (e.g., SiO₂). The insulative structures 104 of the tiers 108 may individually be substantially homogeneous, or the insulative structure 104 of one or more (e.g., each) of the tiers 108 may individually be heterogenous.

The conductive structures 106 of the tiers 108 of the stack structure 102 may individually be formed of and include conductive material, such as one or more of at least one conductively doped semiconductor material, at least one metal, at least one alloy, and at least one conductive metal-containing material (e.g., at last one conductive metal nitride, at least one conductive metal silicide, at least one conductive metal carbide, at least one conductive metal oxide). In some embodiments, each of the conductive structures 106 is formed of and includes W. Optionally, at least one liner material (e.g., at least one insulative liner material, at least one conductive liner material) may be formed around the conductive structures 106. The liner material may, for example, be formed of and include one or more of a metal (e.g., titanium, tantalum), an alloy, a metal nitride (e.g., tungsten nitride, titanium nitride, tantalum nitride), and a metal oxide (e.g., aluminum oxide). In some embodiments, the liner material comprises at least one conductive material employed as a seed material for the formation of the conductive structures 106. In some embodiments, the liner material comprises titanium nitride (TiNₓ, such as TiN). In further embodiments, the liner material further includes aluminum oxide (AlOₓ, such as Al₂O₃). As a non-limiting example, for each of the tiers 108 of the stack structure 102, AlOₓ (e.g., Al₂O₃) may be formed directly adjacent the corresponding insulative structures 104, TiNₓ (e.g., TiN) may be formed directly adjacent the AlOₓ, and W may be formed directly adjacent the TiNₓ. For clarity and case of understanding the description, the liner material is not illustrated in FIGS. 1B and 1C, but it will be understood that the liner material may be disposed around the conductive structures 106. The conductive structures 106 of the tiers 108 of the stack structure 102 may be formed through a so-called “replacement gate” or “gate last” processing wherein sacrificial material (e.g., dielectric nitride material, such as SiN_{y}) of a preliminary stack structure is selectively removed (e.g., using a wet etchant comprising phosphoric acid (H₃PO₄)) relative to insulative material of the insulative structures 104, and then the resulting voids are filled with conductive material to form the conductive structures 106.

As depicted in FIGS. 1A through 1C, the stack structure 102 may be divided (e.g., segmented, partitioned) into blocks 134 separated from one another by dielectric-filled slot structures 140 (e.g., dielectric-filled slits, dielectric-filled openings, dielectric-filled trenches). The dielectric-filled slot structures 140 may vertically extend (e.g., in the Z-direction) completely through the stack structure 102. In FIG. 1A, for clarity and case of understanding the drawings and associated description, the dielectric-filled slot structures 140 are depicted as transparent to more clearly show the stadium structures 112 distributed within the block 134 of the stack structure 102.

Referring to FIGS. 1A and 1B, the blocks 134 and the dielectric-filled slot structures 140 may horizontally extend in parallel in the X-direction (e.g., a first horizontal direction). As used herein, the term “parallel” means substantially parallel. Horizontally neighboring blocks 134 of the stack structure 102 may be separated from one another in the Y-direction (e.g., a second horizontal direction) orthogonal to the X-direction by the dielectric-filled slot structures 140. The dielectric-filled slot structures 140 may also horizontally extend in parallel in the X-direction.

Each of the blocks 134 of the stack structure 102 may exhibit substantially the same geometric configuration (e.g., substantially the same dimensions and substantially the same shape) as each other of the blocks 134, or one or more of the blocks 134 may exhibit a different geometric configuration (e.g., one or more different dimensions and/or a different shape) than one or more other of the blocks 134. In addition, each pair of horizontally neighboring blocks 134 of the stack structure 102 may be horizontally separated from one another by substantially the same distance (e.g., corresponding to a width in the Y-direction of each of the dielectric-filled slot structures 140) as each other pair of horizontally neighboring blocks 134 of the stack structure 102, or at least one pair of horizontally neighboring blocks 134 of the stack structure 102 may be horizontally separated from one another by a different distance than that separating at least one other pair of horizontally neighboring blocks 134 of the stack structure 102. In some embodiments, the blocks 134 of the stack structure 102 are substantially uniformly (e.g., substantially non-variably, substantially equally, substantially consistently) sized, shaped, and spaced relative to one another.

The dielectric-filled slot structures 140 may be formed of and include insulative material. The insulative material may include at least one dielectric material, such as one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and MgOₓ), at least one dielectric nitride material (e.g., SiN_{y}), at least one dielectric oxynitride material (e.g., SiOₓN_{y}), and at least one dielectric carboxynitride material (e.g., SiOₓC_{z}N_{y}). In some embodiments, the dielectric-filled slot structures 140 are formed of and include dielectric oxide material, such as SiOₓ (e.g., SiO₂).

Referring collectively to FIGS. 1A through IC, each block 134 of the stack structure 102 may individually include stadium structures 112, crest regions 122 (e.g., elevated regions), and bridge regions 124 (e.g., additional elevated regions). The stadium structures 112 may be distributed throughout and substantially confined within a horizontal area of the block 134. The crest regions 122 may be horizontally interposed between neighboring stadium structures 112 in the X-direction. The bridge regions 124 may horizontally neighbor opposing sides of individual stadium structures 112 in the Y-direction, and may horizontally extend from and between neighboring crest regions 122 in the X-direction. In FIG. 1A, for clarity and case of understanding the drawings and associated description, portions (e.g., some of the bridge regions 124 horizontally neighboring first sides of the stadium structures 112 in the Y-direction) of one of the blocks 134 of the stack structure 102 are depicted as transparent to more clearly show the stadium structures 112 distributed within the block 134.

As shown in FIG. 1A, at least some (e.g., each) of the stadium structures 112 within an individual block 134 of the stack structure 102 may be positioned at different vertical elevations in the Z-direction than one another. For example, an individual block 134 may include a first stadium structure 112A, a second stadium structure 112B at a relatively lower vertical position (e.g., in the Z-direction) within the block 134 than the first stadium structure 112A, a third stadium structure 112C at a relatively lower vertical position within the block 134 than the second stadium structure 112B, and a fourth stadium structure 112D at a relatively lower vertical position within the block 134 than the third stadium structure 112C. In addition, the stadium structures 112 may be substantially uniformly (e.g., equally, evenly) horizontally spaced apart from one another. In additional embodiments, one or more blocks 134 of the stack structure 102 may individually include a different quantity of stadium structures 112 and/or a different distribution of stadium structures 112 than that depicted in FIG. 1A. For example, an individual block 134 of the stack structure 102 may include greater than four (4) of the stadium structures 112 (e.g., greater than or equal to five (5) of the stadium structures 112, greater than or equal to ten (10) of the stadium structures 112, greater than or equal to twenty-five (25) of the stadium structures 112, greater than or equal to fifty (50) of stadium structures 112), or less than four (4) of the stadium structures 112 (e.g., less than or equal to three (3) of the stadium structures 112, less than or equal to two (2) of the stadium structures 112, only one (1) of the stadium structures 112). As another example, within an individual block 134, stadium structures 112 may be at least partially non-uniformly (e.g., non-equally, non-evenly) horizontally spaced, such that at least one of the stadium structures 112 is separated from at least two other of the stadium structures 112 horizontally neighboring (e.g., in the X-direction) the at least one stadium structures 112 by different (e.g., non-equal) distances. As an additional non-limiting example, within an individual block 134, vertical positions (e.g., in the Z-direction) of the stadium structures 112 may vary in a different manner (e.g., may alternate between relatively deeper and relatively shallower vertical positions) than that depicted in FIG. 1A.

Each stadium structure 112 may include opposing staircase structures 114, and a central region 118 horizontally interposed between (e.g., in the X-direction) the opposing staircase structures 114. The opposing staircase structures 114 of an individual stadium structure 112 may include a forward staircase structure 114A and a reverse staircase structure 114B. A phantom line extending from a top of the forward staircase structure 114A to a bottom of the forward staircase structure 114A may have a positive slope, and another phantom line extending from a top of the reverse staircase structure 114B to a bottom of the reverse staircase structure 114B may have a negative slope. In additional embodiments, one or more of the stadium structures 112 may individually exhibit a different configuration than that depicted in FIG. 1A. As a non-limiting example, an individual stadium structure 112 may be modified to include a forward staircase structure 114A but not a reverse staircase structure 114B (e.g., the reverse staircase structure 114B may be absent), or an individual stadium structure 112 may be modified to include a reverse staircase structure 114B but not a forward staircase structure 114A (e.g., the forward staircase structure 114A may be absent). In such embodiments, the central region 118 horizontally neighbors a bottom of the forward staircase structure 114A (e.g., if the reverse staircase structure 114B is absent), or horizontally neighbors a bottom of the reverse staircase structure 114B (e.g., if the forward staircase structure 114A is absent).

As shown in FIGS. 1A and 1C, the opposing staircase structures 114 (e.g., the forward staircase structure 114A and the reverse staircase structure 114B) of an individual stadium structure 112 may individually include steps 116 defined by edges (e.g., horizontal ends) of the tiers 108 of the stack structure 102 within a horizontal area of an individual block 134 of the stack structure 102. For the opposing staircase structures 114 of an individual stadium structure 112, each step 116 of the forward staircase structure 114A may have a counterpart step 116 within the reverse staircase structure 114B having substantially the same geometric configuration (e.g., shape, dimensions), vertical position (e.g., in the Z-direction), and horizontal distance (e.g., in the X-direction) from a horizontal center (e.g., in the X-direction) of the central region 118 of the stadium structure 112. In additional embodiments, at least one step 116 of the forward staircase structure 114A does not have a counterpart step 116 within the reverse staircase structure 114B having substantially the same geometric configuration (e.g., shape, dimensions), vertical position (e.g., in the Z-direction), and/or horizontal distance (e.g., in the X-direction) from horizontal center (e.g., in the X-direction) of the central region 118 of the stadium structure 112; and/or at least one step 116 of the reverse staircase structure 114B does not have a counterpart step 116 within the forward staircase structure 114A having substantially the same geometric configuration (e.g., shape, dimensions), vertical position (e.g., in the Z-direction), and/or horizontal distance (e.g., in the X-direction) from horizontal center (e.g., in the X-direction) of the central region 118 of the stadium structure 112.

Each of the stadium structures 112 within an individual block 134 of the stack structure 102 may individually include a desired quantity of steps 116. Each of the stadium structures 112 may include substantially the same quantity of steps 116 as each other of the stadium structures 112, or at least one of the stadium structures 112 may include a different quantity of steps 116 than at least one other of the stadium structures 112. In some embodiments, at least one of the stadium structures 112 includes a different (e.g., greater, lower) quantity of steps 116 than at least one other of the stadium structures 112. As shown in FIG. 1A, in some embodiments, the steps 116 of each of the stadium structures 112 are arranged in order, such that steps 116 directly horizontally adjacent (e.g., in the X-direction) one another correspond to tiers 108 of the stack structure 102 directly vertically adjacent (e.g., in the Z-direction) one another. In additional embodiments, the steps 116 of at least one of the stadium structures 112 are arranged out of order, such that at least some steps 116 of the stadium structure 112 directly horizontally adjacent (e.g., in the X-direction) one another correspond to tiers 108 of the stack structure 102 not directly vertically adjacent (e.g., in the Z-direction) one another.

With continued reference to FIGS. 1A and 1C, for an individual stadium structure 112, the central region 118 thereof may horizontally intervene (e.g., in the X-direction) between and separate the forward staircase structure 114A thereof from the reverse staircase structure 114B thereof. The central region 118 may horizontally neighbor a vertically lowermost step 116 of the forward staircase structure 114A, and may also horizontally neighbor a vertically lowermost step 116 of the reverse staircase structure 114B. The central region 118 of an individual stadium structure 112 may have any desired horizontal dimensions. In addition, within an individual block 134, the central region 118 of each of the stadium structures 112 may have substantially the same horizontal dimensions as the central region 118 of each other of the stadium structures 112, or the central region 118 of at least one of the stadium structures 112 may have different horizontal dimensions than the central region 118 of at least one other of the stadium structures 112.

Referring collectively to FIGS. 1A through IC, each stadium structure 112 (including the forward staircase structure 114A, the reverse staircase structure 114B, and the central region 118 thereof) within an individual block 134 of the stack structure 102 may individually partially define boundaries (e.g., horizontal boundaries, vertical boundaries) of a filled trench 120 vertically extending (e.g., in the Z-direction) partially through the stack structure 102. The crest regions 122 and the bridge regions 124 horizontally neighboring an individual stadium structure 112 may also partially define the boundaries of the filled trench 120 associated with the stadium structure 112.

The filled trench 120 may only vertically extend through tiers 108 of the stack structure 102 defining the forward staircase structure 114A and the reverse staircase structure 114B of the stadium structure 112; or may also vertically extend through additional tiers 108 of the stack structure 102 not defining the forward staircase structure 114A and the reverse staircase structure 114B of the stadium structure 112, such as additional tiers 108 of the stack structure 102 vertically overlying the stadium structure 112. Edges of the additional tiers 108 of the stack structure 102 may, for example, define one or more additional stadium structures vertically overlying and horizontally offset from the stadium structure 112. The filled trench 120 may be filled with one or more dielectric materials. For example, as shown in FIGS. 1B and 1C, an individual filled trench 120 may include a first dielectric material 126 (e.g., a dielectric liner material), a second dielectric material 128 (e.g., an additional dielectric liner material), and a third dielectric material 130 (e.g., a dielectric fill material). For an individual filled trench 120 within a horizontal area of an individual block 134 of the stack structure 102, the first dielectric material 126 may be formed on or over surfaces (e.g., horizontally extending surfaces, vertically extending surfaces) of the block 134, the second dielectric material 128 may be formed on or over the first dielectric material 126, and the third dielectric material 130 may be formed on or over the second dielectric material 128. As depicted in FIGS. 1B and 1C, one or more (e.g., each) of the first dielectric material 126, the second dielectric material 128, and the third dielectric material 130 may also be formed to extend beyond boundaries (e.g., horizontal boundaries, vertical boundaries) of the filled trenches 120. For example, first dielectric material 126, the second dielectric material 128, and the third dielectric material 130 may also be formed to extend over uppermost surfaces of an individual block 134 of the stack structure 102. In additional embodiments, the first dielectric material 126 and/or the second dielectric material 128 may be omitted (e.g., absent). In some embodiments, the first dielectric material 126 is formed of and includes SiOₓ (e.g., SiO₂), the second dielectric material 128 is formed of and includes SiN_{y} (e.g., Si₂N₄), and the third dielectric material 130 is formed of and includes additional SiOₓ (e.g., additional SiO₂).

As depicted in FIG. 1A, the crest regions 122 of an individual block 134 of the stack structure 102 may intervene between and separate stadium structures 112 horizontally neighboring one another in the X-direction. For example, one of the crest regions 122 may intervene between and separate the first stadium structure 112A and the second stadium structure 112B; an additional one of the crest regions 122 may intervene between and separate the second stadium structure 112B and a third stadium structure 112C; and a further one of the crest regions 122 may intervene between and separate the third stadium structure 112C and a fourth stadium structure 112D. A vertical height of the crest regions 122 in the Z-direction may be substantially equal to a maximum vertical height of the block 134 in the Z-direction; and a horizontal width of the crest regions 122 in the Y-direction may be substantially equal to a maximum horizontal width of the block 134 in the Y-direction. In addition, each of the crest regions 122 may individually exhibit a desired horizontal length in the X-direction. Each of the crest regions 122 of an individual block 134 of the stack structure 102 may exhibit substantially the same horizontal length in the X-direction as each other of the crest regions 122 of the block 134; or at least one of the crest regions 122 of the block 134 may exhibit a different horizontal length in the X-direction than at least one other of the crest regions 122 of the block 134.

With reference to FIG. 1A, the bridge regions 124 of an individual block 134 of the stack structure 102 may intervene between and separate the stadium structures 112 of the block 134 from the dielectric-filled slot structures 140 horizontally neighboring the block 134 in the Y-direction. For example, for each stadium structure 112 within an individual block 134 of the stack structure 102, a first bridge region 124A may be horizontally interposed in the Y-direction between a first side of the stadium structure 112 and a first side of the dielectric-filled slot structures 140 horizontally neighboring the block 134; and a second bridge region 124B may be horizontally interposed in the Y-direction between a second side of the stadium structure 112 and a second side of the dielectric-filled slot structures 140 horizontally neighboring the block 134. The first bridge region 124A and the second bridge region 124B may horizontally extend in parallel in the X-direction. In addition, the first bridge region 124A and the second bridge region 124B may each horizontally extend from and between neighboring crest regions 122 of the block 134 in the X-direction. The bridge regions 124 of the block 134 may be integral and continuous with the crest regions 122 of the block 134. Upper boundaries (e.g., upper surfaces in the Z-direction) of the bridge regions 124 may be substantially coplanar with upper boundaries of the crest regions 122. A vertical height of the bridge regions 124 in the Z-direction may be substantially equal to a maximum vertical height of the block 134 in the Z-direction. In addition, each of the bridge regions 124 (including each first bridge region 124A and each second bridge region 124B) may individually exhibit a desired horizontal width in the Y-direction and a desired horizontal length in the X-direction. Each of the bridge regions 124 of the block 134 may exhibit substantially the same horizontal length in the X-direction as each other of the bridge regions 124 of the block 134; or at least one of the bridge regions 124 of the block 134 may exhibit a different horizontal length in the X-direction than at least one other of the bridge regions 124 of the block 134. In addition, each of the bridge regions 124 of the block 134 may exhibit substantially the same horizontal width in the Y-direction as each other of the bridge regions 124 of the block 134; or at least one of the bridge regions 124 of the block 134 may exhibit a different horizontal width in the Y-direction than at least one other of the bridge regions 124 of the block 134.

Referring collectively to FIGS. 1B through 1D, within horizontal areas of the blocks 134 of the stack structure 102, the microelectronic device structure 100 further includes additional dielectric-filled slot structures 110 and at least one further dielectric-filled slot structure 111. An individual block 134 of the stack structure 102 may include a group of the additional dielectric-filled slot structures 110 within a horizontal area thereof. An individual block 134 of the stack structure 102 may include greater than one (1) of the additional dielectric-filled slot structures 110 within a horizontal area thereof, such as greater than or equal to two (2) of the additional dielectric-filled slot structures 110, or greater than or equal to three (3) of the additional dielectric-filled slot structures 110. As a non-limiting example depicted in FIG. 1D, a group of the additional dielectric-filled slot structures 110 includes a first additional dielectric-filled slot structure 110₍₁₎ a second additional dielectric-filled slot structure 110₍₂₎; a third additional dielectric-filled slot structure 110₍₃₎ horizontally interposed between the first and second additional dielectric-filled slot structures 110₍₁₎ 110₍₂₎ in the Y-direction; a fourth additional dielectric-filled slot structure 110₍₄₎ horizontally interposed between the first and third additional dielectric-filled slot structures 110₍₁₎, 110₍₃₎ in the Y-direction; and a fifth additional dielectric-filled slot structure 110₍₅₎ horizontally interposed between the third and second additional dielectric-filled slot structures 110₍₃₎, 110₍₂₎ in the Y-direction. The additional dielectric-filled slot structures 110 may vertically extend in the Z-direction partially (e.g., less than completely) through at least some (e.g., each) of the blocks 134 of the stack structure 102.

Within the horizontal area of an individual block 134 of the stack structure 102, a group of the additional dielectric-filled slot structures 110 may be formed to horizontally extend in the X-direction into a horizontal area of an uppermost one of the stadium structures 112 of the block 134. The additional dielectric-filled slot structures 110 of the group may, for example, individually horizontally extend, in the X-direction, partially or completely through a horizontal area of the upper most one of the stadium structures 112. In some embodiments, some of the additional dielectric-filled slot structures 110 (e.g., the first additional dielectric-filled slot structure 110₍₁₎, the second additional dielectric-filled slot structure 110₍₂₎) horizontally terminate (e.g., horizontally end), in the X-direction, at or proximate a relatively lowest step 116 of the one of the opposing staircase structures 114 (e.g., the reverse staircase structure 114B) within vertical boundaries (e.g., in the Z-direction) defined by the relatively vertically higher tiers 108A of the stack structure 102. One of more other of the additional dielectric-filled slot structures 110 (e.g., the third, fourth and fifth additional dielectric-filled slot structure 110₍₃₎, 110₍₄₎, 110₍₅₎ may horizontally terminate (e.g., horizontally end), in the X-direction, at or within one of the crest region 122 horizontally neighboring the uppermost one of the stadium structures 112 (e.g., horizontally adjacent the forward staircase structure 114A thereof in the X-direction). As a non-limiting example shown in FIG. 1D, the third, fourth and fifth additional dielectric-filled slot structure 110₍₃₎, 110₍₄₎, 110₍₅₎ may horizontally extend in the X-direction completely across the stadium structure 112 and may terminate within the crest region 122 adjacent to the stadium structure 112, whereas, the first and second additional dielectric-filled slot structure 110₍₁₎, 110₍₂₎ may horizontally terminate in the X-direction within the stadium structure 112.

In some embodiments, horizontal lengths in X-direction of the first and second additional dielectric-filled slot structures 110₍₁₎, 110₍₂₎ are substantially equal to one another. In additional embodiments, the horizontal lengths in X-direction of the first and second additional dielectric-filled slot structures 110₍₁₎, 110₍₂₎ are different than one another. In some embodiments, one or more (e.g., each) of the first and second additional dielectric-filled slot structures 110₍₁₎, 110₍₂₎ horizontally extends in the X-direction across an entirety of the reverse staircase structure 114B of the stadium structure 112, and horizontally terminates in the X-direction at or within the central region 118 of the stadium structure 112.

In some embodiments, horizontal lengths in X-direction of one or more of the third, fourth, and fifth additional dielectric-filled slot structures 110₍₃₎, 110₍₄₎, 110₍₅₎ are substantially the same as one another. In additional embodiments, a horizontal length in X-direction of one or more (e.g., each) of the third, fourth, and fifth additional dielectric-filled slot structures 110₍₃₎, 110₍₄₎, 110₍₅₎ is different than a horizontal length in the X-direction of one or more (e.g., each) other of the third, fourth, and fifth additional dielectric-filled slot structures 110₍₃₎, 110₍₄₎, 110₍₅₎. In some embodiments, one or more (e.g., each) of the third, fourth, and fifth additional dielectric-filled slot structures 110₍₃₎, 110₍₄₎, 110₍₅₎ horizontally extends in the X-direction across an entirety of the stadium structure 112, and horizontally terminates at or within the crest region 122 horizontally neighboring the forward staircase structure 114A of the stadium structure 112.

Each of the additional dielectric-filled slot structures 110 of the group may vertically terminate in the Z-direction at or within vertical boundaries of the relatively vertically higher tiers 108A of the stack structure 102.

As shown in FIGS. 1B and 1D, for an individual block 134 of the stack structure 102, the additional dielectric-filled slot structures 110 partially define and horizontally separate (e.g., in the Y-direction) sub-blocks 144 of the block. For example, if an individual block 134 includes five (5) of the additional dielectric-filled slot structures 110, the five (5) of the additional dielectric-filled slot structures 110 and the two (2) dielectric-filled slot structures 140 horizontally neighboring the block 134 in the Y-direction may together define six (6) sub-blocks 144 of the block 134. As shown in FIG. 1D, the six (6) sub-blocks 144 may include a first sub-block 144A, a second sub-block 144B, a third sub-block 144C, a fourth sub-block 144D, a fifth sub-block 144E, and a sixth sub-block 144F. The first sub-block 144A may be horizontally interposed in the Y-direction between the first additional dielectric-filled slot structures 110₍₁₎ and one of the dielectric-filled slot structures 140. The second sub-block 144B may be horizontally interposed in the Y-direction between the first additional dielectric-filled slot structure 110₍₁₎ and the fourth additional dielectric-filled slot structure 110₍₄₎. The third sub-block 144C may be horizontally interposed in the Y-direction between the fourth additional dielectric-filled slot structure 110₍₄₎ and the third additional dielectric-filled slot structure 110₍₃₎. The fourth sub-block 144D may be horizontally interposed in the Y-direction between the third additional dielectric-filled slot structure 110₍₃₎ and the fifth additional dielectric-filled slot structure 110₍₅₎. The fifth sub-block 144E may be horizontally interposed in the Y-direction between the third additional dielectric-filled slot structure 110₍₃₎ and the second additional dielectric-filled slot structure 110₍₂₎. The sixth sub-block 144F may be horizontally interposed in the Y-direction between the second additional dielectric-filled slot structure 110₍₂₎ and the other one of the dielectric-filled slot structures 140. The first additional dielectric-filled slot structure 110₍₁₎ horizontally separate (e.g., in the Y-direction) the first sub-block 144A and the second sub-block 144B; the second additional dielectric-filled slot structure 110₍₂₎ horizontally separates the fifth sub-block 144E and the sixth sub-block 144F; the third additional dielectric-filled slot structure 110₍₃₎ horizontally separates third sub-block 144C and the fourth sub-block 144D; the fourth additional dielectric-filled slot structure 110₍₄₎ horizontally separate second sub-block 144B and the third sub-block 144C; and the fifth additional dielectric-filled slot structure 110₍₅₎ horizontally separates the fourth sub-block 144D and the fifth sub-block 144E.

The additional dielectric-filled slot structures 110 and the further dielectric-filled slot structures 111 may comprise slots (e.g., openings, trenches, slits) in the stack structure 102 filled with at least one dielectric material. A material composition of the dielectric material of the additional dielectric-filled slot structures 110 and the further dielectric-filled slot structures 111 may be substantially the same as a material composition of the dielectric material of the dielectric-filled slot structures 140; or the material composition of the dielectric material of the additional dielectric-filled slot structures 110 and/or the further dielectric-filled slot structures 111 may be different than the material composition of the dielectric material of the dielectric-filled slot structures 140. In some embodiments, the additional dielectric-filled slot structures 110 and the further dielectric-filled slot structures 111 are individually formed of and include at least one dielectric oxide material (e.g., SiOₓ, such as SiO₂). In additional embodiments, the additional dielectric-filled slot structures 110 and/or the further dielectric-filled slot structures 111 are formed of and include at least one dielectric nitride material (e.g., SiN_{y}, such as Si₃N₄).

Within an individual block 134 of the stack structure 102, the conductive structures 106 of one or more of the relatively vertically higher tiers 108A segmented by the additional dielectric-filled slot structures 110 may be used as upper select gate structures 156 (e.g., first select gate structures, drain side select gate (SGD) structures) (FIG. 1B) of the block 134. The upper select gate structures 156 may be employed for upper select transistors (e.g., drain side select transistors) of the block 134. In some embodiments, within an individual block 134 of the stack structure 102, the conductive structures 106 of each of less than or equal to eight (8) relatively higher tiers 108A (e.g., from one (1) relatively vertically higher tier 108A to eight (8) relatively vertically higher tiers 108A) of the stack structure 102 are employed to form the upper select gate structures 156 for the block 134. Moreover, within an individual block 134 of the stack structure 102, the conductive structures 106 of at least a vertically lower tier 108B may be employed for at least one lower select gate structure (e.g., at least one second select gate structure, at least one source side select gate (SGS) structure) of the block 134.

In some embodiments, as shown in FIG. 1B, for an individual block 134, an individual vertically higher tier 108A includes six (6) upper select gate structures 156. Each of the upper select gate structures 156 of the vertically higher tier 108A of the block 134 may be positioned within a different one of the six (6) sub-blocks 144 (e.g., sub-blocks 144A, 144B, 144C, 144D, 144E, 144F) of the block 134 than each other of the upper select gate structures 156. The additional dielectric-filled slot structures 110 within a horizontal area of the block 134 may horizontally intervene between (e.g., in the Y-direction) and separate the upper select gate structures 156 of the individual vertically higher tier 108A.

The further dielectric-filled slot structures 111 horizontally extends in the Y-direction and vertically extends in the Z-direction partially through at least some (e.g., each) of the blocks 134 of the stack structure 102. The further dielectric-filled slot structures 111 may respectively be horizontally offset, in the X-direction, from each the uppermost one of the stadium structures 112. As a non-limiting example, the further dielectric-filled slot structures 111 may be within a horizontal area of the crest region 122 adjacent to the uppermost one of the stadium structures 112.

As shown depicted in FIG. 1D, within a horizontal area of an individual block 134, the further dielectric-filled slot structures 111 may not horizontally intersect within the first, second, and third additional dielectric-filled slot structures 110₍₁₎, 110₍₂₎, 110₍₃₎; and may respectively horizontally intersect with one the fourth and fifth additional dielectric-filled slot structures 110₍₄₎, 110₍₅₎. In FIG. 1D, a group of three further dielectric-filled slot structures 111 intersect the fourth additional dielectric-filled slot structures 110₍₄₎, and an additional group of three further dielectric-filled slot structures 111 intersect the fifth additional dielectric-filled slot structures 110₍₅₎. However, the disclosure is not limited, and an individual group of the further dielectric-filled slot structures 111 include more than three (e.g., four, more than four) or less than three (e.g., two, one) further dielectric-filled slot structures 111. Furthermore, the group of further dielectric-filled slot structures 111 horizontally intersecting the fourth additional dielectric-filled slot structures 110₍₄₎ may include different numbers of further dielectric-filled slot structures 111 than the additional group of further dielectric-filled slot structures 111 intersecting the fifth additional dielectric-filled slot structures 110₍₅₎.

Referring collectively to FIGS. 1B through 1D, within horizontal areas of the stadium structures 112, the microelectronic device structure 100 further includes contact structures 136. The contact structures 136 may vertically extend through the filled trenches 120 to at least some of the steps 116 of an individual stadium structure 112. A lower vertical boundary (e.g., a lower surface) of an individual contact structure 136 may physically contact (e.g., land on) the conductive structure 106 of an individual tier 108 of the stack structure 102 at a tread of an individual step 116 of an individual stadium structure 112. In addition, an upper vertical boundary (e.g., an upper surface) of an individual contact structure 136 may be substantially coplanar with an upper vertical boundary (e.g., an upper surface) of an individual filled trench (e.g., an upper vertical boundary of the third dielectric material 130 thereof).

Some of the contact structures 136 may vertically extend to and terminate at relatively vertically higher tiers 108A of the stack structure 102, and may be coupled to the upper select gate structures 156 within the sub-blocks 144 of the block 134. In FIG. 1D, dashed lines are illustrated to depict the dimensions and arrangement of some of the steps 116 of the stadium structure 112. At least some contact structures 136 associated with the same sub-block 144 as one another may be horizontally aligned with one another in the Y-direction.

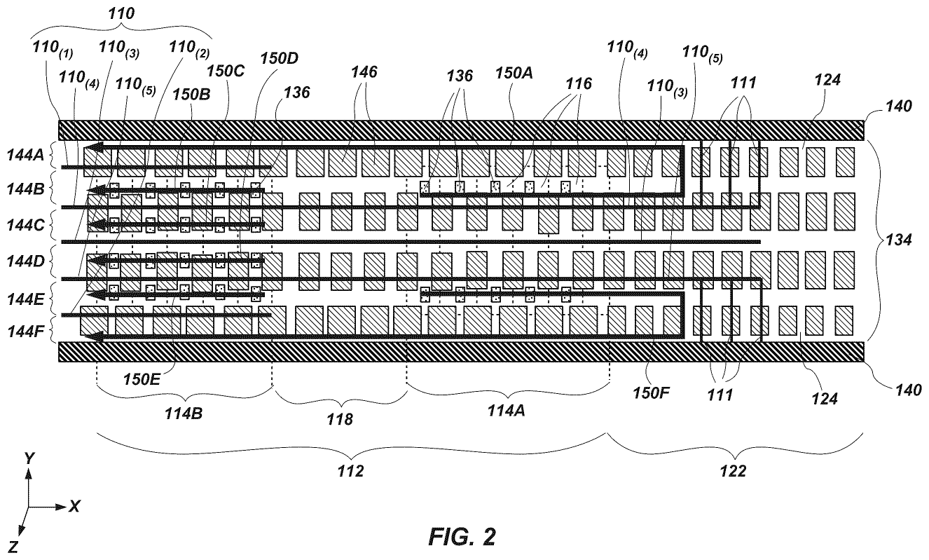

The sub-blocks 144 of an individual block 134 of the stack structure 102 may respectively include at least one group (e.g., row) of the contact structures 136 operatively associated with the upper select gate structures 156 thereof. For some of the sub-blocks 144, the contact structures 136 operatively associated therewith are positioned within a horizontal area of the reverse staircase structure 114B of the stadium structure 112; and for some others of the sub-blocks 144, the contact structures 136 operatively associated therewith are positioned within a horizontal area of the forward staircase structure 114A of the stadium structure 112. For example, groups of the contact structures 136 operatively associated with the first sub-block 144A and the sixth sub-block 144F may respectively land on steps 116 of the forward staircase structure 114A of the stadium structure 112; and additional groups of the contact structures 136 operatively associated with the second sub-block 144B, the third sub-block 144C, the fourth sub-block 144D, and the fifth sub-block 144E may land on steps 116 of the reverse staircase structure 114B of the stadium structure 112. The additional dielectric-filled slot structures 110, the further dielectric-filled slot structure 111, the bridge regions 124, and the conductive structures 106 of the upper tiers 108A of the stack structure 102 may facilitate desirable signal routing paths from different groups (e.g., row) of the contact structures 136 to the upper select gate structures 156 of the sub-blocks 144, as describe in further detail below with reference to FIG. 2.

The contact structures 136 may individually exhibit a desired horizontal cross-sectional shape. In some embodiments, each of the contact structures 136 exhibits a substantially circular horizontal cross-sectional shape. In additional embodiments, one or more (e.g., each) of the contact structures 136 exhibits a non-circular cross-sectional shape, such as one more of an oblong cross-sectional shape, an elliptical cross-sectional shape, a square cross-sectional shape, a rectangular cross-sectional shape, a tear drop cross-sectional shape, a semicircular cross-sectional shape, a tombstone cross-sectional shape, a crescent cross-sectional shape, a triangular cross-sectional shape, a kite cross-sectional shape, and an irregular cross-sectional shape. In addition, each of the contact structures 136 may exhibit substantially the same horizontal cross-sectional dimensions (e.g., substantially the same horizontal diameter), or at least one of the contact structures 136 may be formed to exhibit one or more different horizontal cross-sectional dimensions (e.g., a different horizontal diameter) than at least one other of the contact structures 136. In some embodiments, all of the contact structures 136 are formed to exhibit substantially the same horizontal cross-sectional dimensions.

The contact structures 136 may individually be formed of and include conductive material. As a non-limiting example, the contact structures 136 may individually be formed of and include one or more of at least one metal, at least one alloy, and at least one conductive metal-containing material (e.g., a conductive metal nitride, a conductive metal silicide, a conductive metal carbide, a conductive metal oxide). A material composition of the contact structures 136 may be substantially the same as a material composition of the conductive structures 106 of the tiers 108 of the stack structure 102, or the material composition of the contact structures 136 may be different than the material composition of the conductive structures 106 of the tiers 108 of the stack structure 102. In some embodiments, the contact structures 136 are individually formed of and include W. The contact structures 136 may individually be homogeneous, or the contact structures 136 may individually be heterogeneous.

Referring collectively to FIGS. 1C and 1D, the microelectronic device structure 100 may further include support structures 146. The support structures 146 vertically extend (e.g., in the Z-direction) through the filled trenches 120 (including the third dielectric material 130, the second dielectric material 128, and the first dielectric material 126 thereof) and through portions of the stack structure 102 vertically underlying and within horizontal areas of the filled trenches 120. Configurations and arrangements of the support structures 146 may be selected to mitigate (e.g., prevent) undesirable tier damage (e.g., tier collapse) during so-called “replacement gate” processes to form the conductive structures 106 of the tiers 108 of the stack structure 102.

As shown in FIG. 1D, within an individual block 134 of the stack structure 102, at least one array of the support structures 146 may include rows of the support structures 146 extending in the X-direction, and columns of the support structures 146 extending in the Y-direction. The array of the support structures 146 may, for example, include rows of the support structures 146 extending in parallel the X-direction. In some embodiments, the array of the support structures 146 includes at least four (4) rows of the support structures 146. The support structures 146 within in each of the rows of the support structures 146 may individually have substantially the same configuration (e.g., shape, dimensions) and arrangement as each of the support structures 146 within each other of the rows of the support structures 146; or at least one the support structures 146 within at least one of the rows of the support structures 146 may have one or more of a different configuration (e.g., a different shape, at least one different dimension) and a different arrangement than at least one of the support structures 146 within at least one other of the rows of the support structures 146. In addition, a group of the support structures 146 of the array within horizontal areas of steps 116 of the stadium structure 112 defined by the vertically higher tiers 108A may have a different arrangement than an additional group of the support structures 146 of the array within horizontal areas of steps 116 of the stadium structure 112 defined by the vertically lower tiers 108B. Furthermore, a group of the support structures 146 within a horizontal area of the forward staircase structure 114A of the stadium structure 112 may have a different arrangement than another group of the support structures 146 within a horizontal area of the reverse staircase structure 114B of the stadium structure 112.

Within a horizontal area of the stadium structure 112 of an individual block 134 of the stack structure 102, an arrangement of the support structures 146 may at least partially depend on an arrangement of the contact structures 136. Horizontal centers of the support structures 146 of an individual row of the support structures 146 may be substantially horizontally aligned or offset with horizontal centers of the contact structures 136 in X-direction or Y-direction. As a non-limiting example shown in FIG. 1D, rows of the support structures 146 may be at least partially horizontally offset in the Y-direction from rows of the contact structures 136.

The support structures 146 may individually be formed of and include one or more of conductive material, insulative material, and semiconductive material. In some embodiments, the support structures 146 are individually formed of and include conductive material, such as one or more of at least one metal (e.g., W, Ti, Mo, Nb, V, Hf, Ta, Cr, Zr, Fe, Ru, Os, Co, Rh, Ir, Ni, Pd, Pt, Cu, Ag, Au, Al), at least one alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a Mg-based alloy, a Ti-based alloy, a steel, a low-carbon steel, a stainless steel), at least one conductive metal-containing material (e.g., a conductive metal nitride, a conductive metal silicide, a conductive metal carbide, a conductive metal oxide), and at least one conductively-doped semiconductor material (e.g., conductively-doped Si, conductively-doped Ge, conductively-doped SiGe). In additional embodiments, one or more of the support structures 146 are formed of and include one or more of insulative structure and semiconductive material. The support structures 146 may individually be formed of and include a single (e.g., only one) material, or may individually be formed of and include multiple (e.g., more than one) materials. By way of non-limiting example, the support structures 146 may individually be formed to include a conductive core material surrounded by an insulative liner material. The insulative liner material may substantially surround (e.g., substantially horizontally and vertically cover) sidewalls of the conductive core material of the support structures 146. The insulative liner material may be horizontally interposed between the conductive core material of the support structures 146 and the tiers 108 (including the conductive structures 106 and the insulative structures 104 thereof) of the stack structure 102.

FIG. 2 is a simplified, partial top-down view of the microelectronic device structure 100 showing signal routing paths 150A through 150E (collectively referred to herein as signal routing paths 150) facilitated by the structural configuration of the microelectronic device structure 100, in accordance with embodiments of the disclosure. The signal routing paths 150 facilitate directing signals received by different groups (e.g., row) of the contact structures 136 to the upper select gate structures 156 (e.g., SGD structures) within different sub-blocks 144 of an individual block 134 of the stack structures 102.

A first signal routing path 150A for the first sub-block 144A may horizontally extend from a first group of the contact structures 136 on some of the steps 116 of the forward staircase structure 114A of the stadium structure 112, across portions of conductive structures 106 (FIG. 1C) of the upper tiers 108A (FIG. 1C) horizontally bounded by the fourth additional dielectric-filled slot structure 110₍₄₎ and at least one of the further dielectric-filled slot structures 111, across additional portions of conductive structures 106 (FIG. 1C) of the upper tiers 108A (FIG. 1C) at least partially defining one of the bridge regions 124, and to upper select gate structures 156 of the first sub-block 144A horizontally bounded by one of the dielectric-filled slot structures 140 and the first additional dielectric-filled slot structure 110₍₄₎.

A second signal routing path 150B for the second sub-block 144B may horizontally extend from a second group of the contact structures 136 on some of the steps 116 of the reverse staircase structure 114B to upper select gate structures 156 of the second sub-block 144B horizontally bounded by the first additional dielectric-filled slot structure 110₍₁₎ and the fourth additional dielectric-filled slot structure 110₍₄₎.

A third signal routing path 150C for the third sub-block 144C may horizontally extend from a third group of the contact structures 136 on some other of the steps 116 of the reverse staircase structure 114B to upper select gate structures 156 of the third sub-block 144C horizontally bounded by the fourth additional dielectric-filled slot structure 110₍₄₎ and the third additional dielectric-filled slot structure 110₍₃₎.

A fourth signal routing path 150D for the fourth sub-block 144D may horizontally extend from a fourth group of the contact structures 136 on yet some other of the steps 116 of the reverse staircase structure 114B to upper select gate structures 156 of the fourth sub-block 144D horizontally bounded the third additional dielectric-filled slot structure 110₍₃₎ and the fifth additional dielectric-filled slot structure 110₍₅₎.

A fifth signal routing path 150E for the fifth sub-block 144E may horizontally extend from a fifth group of the contact structures 136 on yet still some other of the steps 116 of the reverse staircase structure 114B to upper select gate structures 156 of the fifth sub-block 144E horizontally bounded the fifth additional dielectric-filled slot structure 110₍₅₎ and the second additional dielectric-filled slot structure 110₍₂₎.

A sixth signal routing path 150F for the sixth sub-block 144F may horizontally extend from a sixth group of the contact structures 136 on some other of the steps 116 of the forward staircase structure 114A of the stadium structure 112, across portions of conductive structures 106 (FIG. 1C) of the upper tiers 108A (FIG. 1C) horizontally bounded by the fifth additional dielectric-filled slot structure 110₍₅₎ and at least one other of the further dielectric-filled slot structures 111, across additional portions of conductive structures 106 (FIG. 1C) of the upper tiers 108A (FIG. 1C) at least partially defining one other of the bridge regions 124, and to upper select gate structures 156 of the sixth sub-block 144F horizontally bounded by another one of the dielectric-filled slot structures 140 and the second additional dielectric-filled slot structure 110₍₂₎.

Thus, in accordance with embodiments of the disclosure, a microelectronic device comprises a stack structure, additional dielectric-filled slot structures, and further dielectric-filled slot structures. The stack structure includes a vertically alternating sequence of conductive structures and insulative structures arranged in tiers. The stack structure further includes blocks separated from one another by dielectric-filled slot structures. At least one of the blocks includes a stadium structure, a crest region horizontally neighboring the stadium structure in a first direction; and a bridge region integral with the crest region and horizontally interposed between the dielectric-filled slot structures and the stadium structure in a second direction orthogonal to the first direction (e.g., Y-direction). The stadium structure includes staircase structures having steps comprising edges of the tiers of the stack structure. The additional dielectric-filled slot structures are within a horizontal area of the at least one of the blocks. The additional dielectric-filled slot structures are separated from one another in the second direction, and individually vertically extend through an upper group of the tiers of the stack structure. The additional dielectric-filled slot structures include a first group of the additional dielectric-filled slot structures extending horizontally in the first direction and terminated within the stadium structure, and a second group of the additional dielectric-filled slot structures extending horizontally in the first direction across the stadium structure and terminated within the crest region. The further dielectric-filled slot structures extends horizontally in the second direction partially into the crest region and vertically through the upper group of the tiers of the stack structure. The further dielectric-filled slot structures respectively horizontally intersect one of the additional dielectric-filled slot structures of the second group of the additional dielectric-filled slot structures.

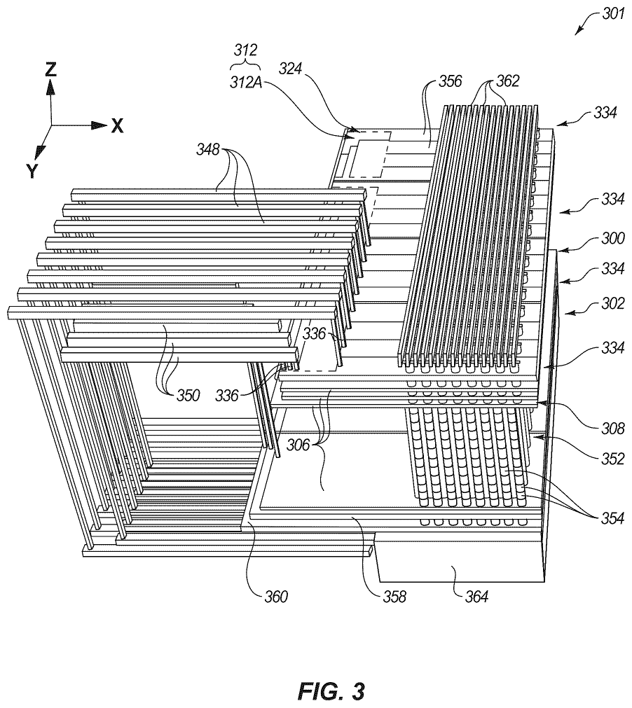

Before referring to FIG. 3, it will be understood that in FIG. 3 and the associated description, and features (e.g., regions, materials, structures, devices) functionally similar to previously described features (e.g., previously described materials, structures, devices) are referred to with similar reference numerals incremented by 100. To avoid repetition, not all features shown in FIG. 3 are described in detail herein. Rather, unless described otherwise below, a feature shown in FIG. 3 designated by a reference numeral that is a 100 increment of the reference numeral of a feature previously described with reference to one or more of FIGS. 1A through 1D and 2 will be understood to be substantially similar to and have substantially the same advantages as the previously described feature. As non-limiting examples, unless described otherwise below, features designated by the reference numeral in FIG. 3 will be understood to be substantially similar to and have substantially the same function as the contact structures 136 previously described herein with reference to FIGS. 1A through 1D and 2. In addition, for clarity and ease of understanding the drawings and related description, some features (e.g., structures, materials, regions, devices) previously described with reference to one or more of FIGS. 1A through 1D and 2 may not be depicted in FIG. 3. However, unless described otherwise below, it will be understood that any features of the microelectronic device structure 100 previously described with reference to one or more of FIGS. 1A through 1D and 2 fall under the scope of this disclosure, and thus may be included in the configurations described below with reference to FIG. 3.

The microelectronic device structure 100 of the disclosure may be included in microelectronic devices of the disclosure. For example, FIG. 3 illustrates a partial cutaway perspective view of a portion of a microelectronic device 301 (e.g., a memory device, such as a 3D NAND Flash memory device) including a microelectronic device structure 300. The microelectronic device structure 300 may be substantially similar to one of the microelectronic device structure 100 (FIGS. 1A through 1D and 2) previously described herein.

As shown in FIG. 3, in addition to the features of the microelectronic device structure 300 previously described herein in relation to the microelectronic device structure 100 (FIGS. 1A through ID and 2), the microelectronic device 301 may further include cell pillar structures 352 vertically extending through at least some of the blocks 334 of the stack structure 302. The cell pillar structures 352 may be positioned within regions (e.g., memory array regions) of the blocks 334 horizontally offset (e.g., in the X-direction) from the stadium structures 312 (e.g., the first stadium structure 312A) (and, hence, the bridge regions 324) of the blocks 334. Intersections of the cell pillar structures 352 and the conductive structures 306 of the tiers 308 of the stack structure 302 within the horizontal areas of the blocks 334 form strings of memory cells 354 vertically extending through the blocks 334 of the stack structure 302. For each string of memory cells 354, the memory cells 354 thereof may be coupled in series with one another. Within an individual block 334, the conductive structures 306 of some of the tiers 308 of the stack structure 302 may serve as access line structures (e.g., word line structures) for the strings of memory cells 354 within the horizontal area of the block 334. In some embodiments, within an individual block 334, the memory cells 354 formed at the intersections of the conductive structures 306 of some of the tiers 308 and the cell pillar structures 352 comprise so-called “MONOS” (metal-oxide-nitride-oxide-semiconductor) memory cells. In additional embodiments, the memory cells 354 comprise so-called “TANOS” (tantalum nitride-aluminum oxide-nitride-oxide-semiconductor) memory cells, or so-called “BETANOS” (band/barrier engineered TANOS) memory cells, each of which are subsets of MONOS memory cells. In further embodiments, the memory cells 354 comprise so-called “floating gate” memory cells including floating gates (e.g., metallic floating gates) as charge storage structures. The floating gates may horizontally intervene between central structures of the cell pillar structures 352 and the conductive structures 306 of the different tiers 308 of the stack structure 302.

The microelectronic device 301 may further include at least one source structure 360, access line routing structures 350, one or more lower select gate structures 358 (e.g., source select gate (SGS) structures), and digit line structures 362. The digit line structures 362 may vertically overlie and be coupled to the cell pillar structures 352 (and, hence, the strings of memory cells 354). The source structure 360 may vertically underlie and be coupled to the cell pillar structures 352 (and, hence, the strings of memory cells 354). In addition, the contact structures 336 may couple various features of the microelectronic device 301 to one another as shown (e.g., the select line routing structures 348 to the upper select gate structures 356; the access line routing structures 350 to the conductive structures 306 of the tiers 308 of the stack structure 302 underlying the upper select gate structures 356 and defining access line structures of the microelectronic device 301).

The microelectronic device 301 may also include a base structure 364 positioned vertically below the cell pillar structures 352 (and, hence, the strings of memory cells 354). The base structure 364 may include at least one control logic region including control logic devices configured to control various operations of other features (e.g., the strings of memory cells 354) of the microelectronic device 301. As a non-limiting example, the control logic region of the base structure 364 may further include one or more (e.g., each) of charge pumps (e.g., V_{CCP} charge pumps, V_{NEGWL} charge pumps, DVC2 charge pumps), delay-locked loop (DLL) circuitry (e.g., ring oscillators), Vad regulators, drivers (e.g., string drivers), page buffers, decoders (e.g., local deck decoders, column decoders, row decoders), sense amplifiers (e.g., equalization (EQ) amplifiers, isolation (ISO) amplifiers, NMOS sense amplifiers (NSAs), PMOS sense amplifiers (PSAs)), repair circuitry (e.g., column repair circuitry, row repair circuitry), I/O devices (e.g., local I/O devices), memory test devices, MUX, error checking and correction (ECC) devices, self-refresh/wear leveling devices, and other chip/deck control circuitry. The control logic region of the base structure 364 may be coupled to the source structure 360, the access line routing structures 350, the select line routing structures 348, and the digit line structures 362. In some embodiments, the control logic region of the base structure 364 includes CMOS (complementary metal-oxide-semiconductor) circuitry. In such embodiments, the control logic region of the base structure 364 may be characterized as having a “CMOS under Array” (“CuA”) configuration.

Thus, in accordance with embodiments of the disclosure, a memory device comprises a stack structure comprising blocks horizontally extending in parallel in a first direction separated from one another in a second direction orthogonal to the first direction by dielectric-filled slot structures. The blocks comprises tiers vertically stacked relative to one another, a stadium structure including opposing staircase structures respectively having steps comprising edges of the tiers, and six sub-block regions. The tiers individually comprises conductive material vertically neighboring insulative material. The six sub-block regions partially defined by five additional dielectric-filled slot structures horizontally extending in parallel in the first direction and vertically extending through an upper group of the tiers. The memory device further comprises strings of memory cells within horizontal areas of and vertical extending through the blocks of the stack structure.

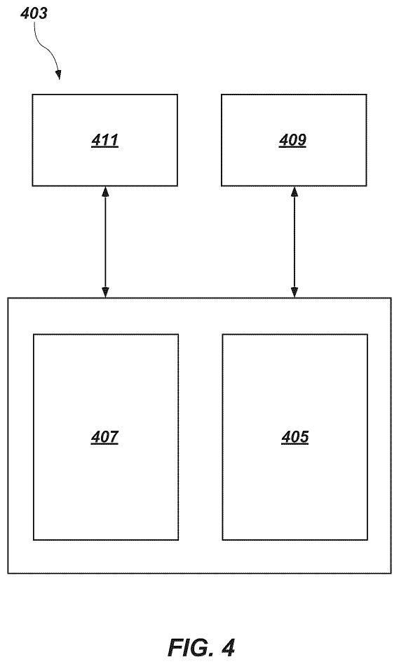

Microelectronic devices structures (e.g., the microelectronic device structure 100 (FIGS. 1A through 1D and 2)) and microelectronic devices (e.g., the microelectronic device 301 (FIG. 3)) in accordance with embodiments of the disclosure may be used in embodiments of electronic systems of the disclosure. For example, FIG. 4 is a block diagram of an electronic system 403 according to embodiments of disclosure. The electronic system 403 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPad® or SURFACE® tablet, an electronic book, a navigation device, etc. The electronic system 403 includes at least one memory device 405. The memory device 405 may comprise, for example, one or more of a microelectronic device structure (e.g., the microelectronic device structure 100 (FIGS. 1A through 1D and 2)) and a microelectronic device (e.g., the microelectronic device 301 (FIG. 3)). The electronic system 403 may further include at least one electronic signal processor device 407 (often referred to as a “microprocessor”). The electronic signal processor device 407 may, optionally, include one or more of a microelectronic device structure (e.g., the microelectronic device structure 100 (FIGS. 1A through 1D and 2)) and a microelectronic device (e.g., the microelectronic device 301 (FIG. 3)). While the memory device 405 and the electronic signal processor device 407 are depicted as two (2) separate devices in FIG. 4, in additional embodiments, a single (e.g., only one) memory/processor device having the functionalities of the memory device 405 and the electronic signal processor device 407 may be included in the electronic system 403. In such embodiments, the memory/processor device may include one or more of a microelectronic device structure (e.g., the microelectronic device structure 100 (FIGS. 1A through 1D and 2)) and a microelectronic device (e.g., the microelectronic device 301 (FIG. 3)). The electronic system 403 may further include one or more input devices 409 for inputting information into the electronic system 403 by a user, such as, for example, a mouse or other pointing device, a keyboard, a touchpad, a button, or a control panel. The electronic system 403 may further include one or more output devices 411 for outputting information (e.g., visual or audio output) to a user such as, for example, a monitor, a display, a printer, an audio output jack, a speaker, etc. In some embodiments, the input device 409 and the output device 411 comprise a single touchscreen device that can be used both to input information to the electronic system 403 and to output visual information to a user. The input device 409 and the output device 411 may communicate electrically with one or more of the memory device 405 and the electronic signal processor device 407.

Thus, in accordance with embodiments of the disclosure, an electronic system comprises an input device, an output device, a processor device, and a memory device. The processor device is operably coupled to the input device and the output device. The memory device is operably coupled to the processor device. The memory device comprises a stack structure having tiers, wherein each tier includes conductive material vertically neighboring insulative material. The stack structure is divided into blocks separated from one another by dielectric-filled slot structures. The blocks comprises a stadium structure, a crest region horizontally neighboring the stadium structure in a first direction, and a bridge region integral with the crest region and horizontally interposed between the dielectric-filled slot structures and the stadium structure in a second direction orthogonal to the first direction. The stadium structure includes staircase structures having steps comprising edges of an upper group of the tiers of the stack structure. The blocks further comprise five additional dielectric-filled slot structures partially defining six sub-block regions. The five additional dielectric-filled slot structures vertically extends through the upper group of the tiers of the stack structures. The five additional dielectric-filled slot structures horizontally extends in parallel with one another in the first direction, and horizontally alternating with the six sub-blocks in the second direction. Additionally, the blocks comprise two further dielectric-filled slot structures within the crest region. The two dielectric-filled slot structures vertically extends through the upper group of the tiers of the stack structures. The two dielectric-filled slot structures horizontally extends in the second direction from one of the dielectric-filled slot structures to one of the five dielectric-filled slot structures. The memory device further comprises strings of memory cells vertically extending through the blocks.

The structures, devices, and methods of the disclosure advantageously facilitate one or more of improved microelectronic device performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, conventional devices, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalents. For example, elements and features disclosed in relation to one embodiment of the disclosure may be combined with elements and features disclosed in relation to other embodiments of the disclosure.

What is claimed is:

1. A microelectronic device, comprising:
a stack structure including a vertically alternating sequence of conductive structures and insulative structures arranged in tiers, the stack structure comprising blocks separated from one another by dielectric-filled slot structures, at least one of the blocks comprising:
a stadium structure including staircase structures having steps comprising edges of the tiers of the stack structure;
a crest region horizontally neighboring the stadium structure in a first direction; and
bridge regions integral with the crest region and horizontally interposed between the dielectric-filled slot structures and the stadium structure in a second direction orthogonal to the first direction;
additional dielectric-filled slot structures within a horizontal area of the at least one of the blocks, the additional dielectric-filled slot structures separated from one another in the second direction and individually vertically extending through an upper group of the tiers of the stack structure,
a first group of the additional dielectric-filled slot structures horizontally extending in the first direction and terminating within the stadium structure,
a second group of the additional dielectric-filled slot structures horizontally extending in the first direction across the stadium structure and terminating within the crest region; and
further dielectric-filled slot structures horizontally extending in the second direction partially into the crest region and vertically through the upper group of the tiers of the stack structure, the further dielectric-filled slot structures respectively horizontally intersecting one of the additional dielectric-filled slot structures of the second group of the additional dielectric-filled slot structures.

2. The microelectronic device of claim 1, wherein:
the first group of the additional dielectric-filled slot structures comprises:
a first additional dielectric-filled slot structure; and
a second additional dielectric-filled slot structure horizontally separated from the first additional dielectric-filled slot structure in the second direction; and
the second group of the additional dielectric-filled slot structures comprises:
a third additional dielectric-filled slot structure horizontally interposed between the first additional dielectric-filled slot structure and the second additional dielectric-filled slot structure in the second direction;
a fourth additional dielectric-filled slot structure horizontally interposed between the first additional dielectric-filled slot structure and the third additional dielectric-filled slot structure in the second direction; and
a fifth additional dielectric-filled slot structure horizontally interposed between the second additional dielectric-filled slot structure and the third additional dielectric-filled slot structure in the second direction.

3. The microelectronic device of claim 2, wherein one of the further dielectric-filled slot structure intersects one of the fourth additional dielectric-filled slot structure and the fifth additional dielectric-filled slot structure.

4. The microelectronic device of claim 2, wherein the first additional dielectric-filled slot structure and the second additional dielectric-filled slot structures respectively horizontally extend into and terminate within a horizontal area of the stadium structure.

5. The microelectronic device of claim 2, wherein the third additional dielectric-filled slot structure, the fourth additional dielectric-filled slot structure, and the fifth additional dielectric-filled slot structure horizontally extend in the first direction across the stadium structure and terminate within the crest region.

6. The microelectronic device of claim 1, further comprising rows of conductive contact structures extending horizontally in the first direction and separated horizontally from one another in the second direction, each of the conductive contact structures in physical contact with one of the steps of the stadium structure.

7. The microelectronic device of claim 6, wherein:
the stadium structure includes a reverse staircase structure, a forward staircase structure, and a central region interposed between the reverse staircase structure and the forward staircase structure in the first direction; and
the rows of conductive contact structures comprise:
first rows of the conductive contact structures in physical contact with the steps of the reverse staircase structure; and
second rows of the conductive contact structures in physical contact with the steps of the forward staircase structure.

8. The microelectronic device of claim 7, wherein:
the first rows of the conductive contact structures comprise three of the first rows of the conductive contact structures; and
the second rows of the conductive contact structures comprise two of the second rows of the conductive contact structures, the two of the second rows of the conductive contact structures horizontally overlapping two of the three of the first rows of the conductive contact structures in the second direction.

9. A memory device, comprising:
a stack structure comprising blocks horizontally extending in parallel in a first direction separated from one another in a second direction orthogonal to the first direction by dielectric-filled slot structures, the blocks respectively comprising:
tiers vertically stacked relative to one another and individually comprising conductive material vertically neighboring insulative material;
a stadium structure including opposing staircase structures respectively having steps comprising edges of the tiers; and
six sub-block regions partially defined by five additional dielectric-filled slot structures horizontally extending in parallel in the first direction and vertically extending through an upper group of the tiers; and
strings of memory cells within horizontal areas of and vertical extending through the blocks of the stack structure.

10. The memory device of claim 9, wherein, for respective ones of the blocks:
the opposing staircase structures of the stadium structure comprise a forward staircase structure and a reverse staircase structure; and
the five additional dielectric-filled slot structures comprise:
two outer additional dielectric-filled slot structures horizontally extending in the first direction through the reverse staircase structure but not the forward staircase structure;
two inner additional dielectric-filled slot structures horizontally interposed between the two outer additional dielectric-filled slot structures in the second direction, the two inner additional dielectric-filled slot structures horizontally extending in the first direction through each of the forward staircase structure and the reverse staircase structure; and
a central additional dielectric-filled slot structure horizontally interposed between the two inner additional dielectric-filled slot structures in the second direction, the central additional dielectric-filled slot structure horizontally extending in the first direction through each of the forward staircase structure and the reverse staircase structure.

11. The memory device of claim 10, further comprising further dielectric-filled slot structures horizontally extending in the second direction and offset the stadium structure in the first direction, the further dielectric-filled slot structures comprising:
a first group of the further dielectric-filled slot structures horizontally extending from one of the five additional dielectric-filled structures to one of the two inner additional dielectric-filled slot structures; and
a second group of the further dielectric-filled slot structures horizontally extending from an other one of the five additional dielectric-filled structures to an other one of the two inner additional dielectric-filled slot structures.

12. The memory device of claim 11, wherein:
the first group the further dielectric-filled slot structures comprises three of the further dielectric-filled slot structures, each of the three of the further dielectric-filled slot structures horizontally intersecting the one of the two inner additional dielectric-filled slot structures; and
the second group the further dielectric-filled slot structures comprises another three of the further dielectric-filled slot structures, each of the another three of the further dielectric-filled slot structures horizontally intersecting the other one of the two inner additional dielectric-filled slot structures.

13. The memory device of claim 10, wherein each of the six sub-blocks includes upper select gate structures, the six sub-blocks comprising:
two outer sub-blocks respectively horizontally interposed in the second direction between one of the outer additional dielectric-filled slot structures and one of the dielectric-filled slot structures,
two inner sub-blocks respectively horizontally interposed in the second direction between the one of the outer additional dielectric-filled slot structures and one of the two inner dielectric-filled slot structures; and
two central sub-blocks respectively horizontally interposed in the second direction between the one of the inner additional dielectric-filled slot structures and the central additional dielectric-filled slot structure.

14. The memory device of claim 10, further comprising, for respective ones of the blocks:
conductive contact structures in physical contact with the steps of the stadium structure; and
support structures within a horizontal area of the stadium structure and extending vertically through the tiers, the support structures horizontally offset from to the conductive contact structures.

15. An electronic system, comprising:
an input device;
an output device;
a processor device operably coupled to the input device and the output device; and
a memory device operably coupled to the processor device and comprising:
a stack structure having tiers, each tier including conductive material vertically neighboring insulative material, the stack structure divided into blocks separated from one another by dielectric-filled slot structures, the blocks respectively comprising:
a stadium structure including staircase structures having steps comprising edges of an upper group of the tiers of the stack structure;
a crest region horizontally neighboring the stadium structure in a first direction;
a bridge region integral with the crest region and horizontally interposed between the dielectric-filled slot structures and the stadium structure in a second direction orthogonal to the first direction;
five additional dielectric-filled slot structures partially defining six sub-block regions, the five additional dielectric-filled slot structures vertically extending through the upper group of the tiers of the stack structures, horizontally extending in parallel with one another in the first direction, and horizontally alternating with the six sub-blocks in the second direction; and
two further dielectric-filled slot structures within the crest region, the two further dielectric-filled slot structures vertically extending through the upper group of the tiers of the stack structures, and respectively horizontally extending in the second direction from one of the dielectric-filled slot structures to one of the five additional dielectric-filled slot structures; and
strings of memory cells vertically extending through the blocks.

16. The electronic system of claim 15, wherein the five additional dielectric-filled slot structures comprise two peripheral additional dielectric-filled slot structures spaced apart horizontally from one another other in the second direction.

17. The electronic system of claim 16, wherein the five additional dielectric-filled slot structures further comprises two inner additional dielectric-filled slot structures interposed horizontally between the two peripheral additional dielectric-filled slot structures in the second direction.

18. The electronic system of claim 17, wherein the five additional dielectric-filled slot structures further comprises one central additional dielectric-filled slot structure interposed horizontally between the two inner additional dielectric-filled slot structures in the second direction.

19. The electronic system of claim 15, wherein the two further dielectric-filled slot structure are horizontally offset from two peripheral additional dielectric-filled slot structures in the first direction and horizontally intersect two inner additional dielectric-filled slot structures.

20. The electronic system of claim 15, wherein the memory device comprises a 3D NAND Flash memory device.
